(19) United States
(12) Patent Application Publication
(10) Pub. No.: US 2007/0259457 A1
(43) Pub. Date: Nov. 8, 2007

(54) Optical endpoint detection of planarization

(75) Inventor: Anthony DiCarlo, Richardson, TX (US)

Correspondence Address: TEXAS INSTRUMENTS INCORPORATED, P O BOX 655474, M/S 3999, DALLAS, TX, 75265, US

(73) Assignee: Texas Instruments

(21) Appl. No.: 11/417,034

(22) Filed: May 4, 2006

(51) Int. Cl. H01L 21/66; H01L 21/4763; H01L 21/302

(52) U.S. Cl. 438/16; 438/725; 438/636; 257/E21.528; 257/E21.029

(57) ABSTRACT

In accordance with the invention, there is a semiconductor device comprising optical enhancement medium and there are methods of end point detection in an etching process and also in a planarization process using an optical enhancement medium such as an anti-reflective coating. The method can include forming a semiconductor structure having at least one trench in a first layer, forming a layer of anti-reflective coating over the first layer, depositing a second layer of material over the anti-reflective layer, and etching the second layer and the anti-reflective layer. The method can also include monitoring an optical signal from the etching process and stopping the etching process at a predetermined time after observing the optical signal from a plasma enhanced optical excitation of the anti-reflective coating and thereby detecting an endpoint of the etching process.

### FIELD OF THE INVENTION

The subject matter of this invention relates to fabricating a semiconductor device. More particularly, the subject matter of this invention relates to methods of utilizing an anti-reflective coating as an optical signal medium for endpoint detection of resist etch back planarization.

### BACKGROUND OF THE INVENTION

Semiconductor devices are manufactured using a series of basic steps involving depositing material onto a substrate, patterning using photo-lithography, and etching. Often new layers and structures are formed over previous layers and structures. Depending on the end product desired, the interim steps may have a non-planar topography, and the end product may require planar topography. Also the new layer may require photo-lithography which in turn will require stringent planarity. As such, the planarity requirement in photo-lithography is becoming more critical with increasing wafer size and decreasing line width.

To achieve planar topography, a sacrificial layer of resist or some other material is deposited over the non-planar surface to fill up trenches, vias, holes, etc., followed by either etching, ashing, or chemical mechanical polishing to achieve surface planarization. Resist etch back is a commonly used technique for planarization. Precise end point detection for resist etch back is critical for allowing optimal post etch back flatness. Therefore, it is important to stop the etching as close to the point of completion as possible.

While some planarization techniques use optical endpoint detection, the resist etch back process does not. Rather, the resist etch back process is a “timed” etch back process. The resist etch process, as currently used, is inaccurate and can lead to over-etching or under-etching. Thus, there is a need for a more accurate determination of the endpoint.

Accordingly, the present invention solves these and other problems of the prior art by utilizing, among other things, an anti-reflective coating as an optical signal medium for the endpoint detection of the resist etch back planarization.

### SUMMARY OF THE INVENTION

In accordance with the invention, there is a new and simple method of endpoint detection for an etching process. The method can comprise forming a semiconductor structure having at least one trench in a first layer, forming a layer of anti-reflective coating over the first layer, depositing a second layer of material over the anti-reflective layer, and etching the second layer and the anti-reflective layer. The method can also include monitoring a signal from the etching process and stopping the etching process at a predetermined time after observing a signal corresponding to the anti-reflective coating and thereby detecting an endpoint of the etching process. The monitored signal can be one of an optical signal, a radio frequency power signal, or an impedance change.

According to another embodiment, there is a planarization process that can comprise forming a layer of an optical enhancement medium over a patterned surface comprising at least one trench, depositing a layer of resist over the optical enhancement medium, and etching the resist layer and the optical enhancement medium layer. This can be followed by optically monitoring the etching process and stopping the etching at a predetermined time after the first observation of the optical signal from the optical enhancement medium.

According to yet another embodiment, a semiconductor device can be fabricated to comprise a semiconductor substrate, a first layer disposed over the semiconductor substrate, wherein the first layer comprises at least one trench, a metal layer disposed over the first resist layer, an optical enhancement medium disposed over at least one trench and over the metal layer, and a layer of planarization material disposed over the optical enhancement medium layer.

According to certain embodiment of the present invention, there is a method of making a semiconductor device. The method can comprise forming a semiconductor substrate, forming a first layer disposed over the semiconductor substrate, wherein the first layer comprises at least one trench, and forming a metal layer disposed over the first layer. The method can also comprise forming an optical enhancement medium layer disposed over at least one trench and over the metal layer, and forming a layer of planarization material disposed over the optical enhancement medium layer.

Additional advantages of the embodiments will be set forth in part in the description which follows, and in part will be obvious from the description, or may be learned by practice of the invention. The advantages will be realized and attained by means of the elements and combinations particularly pointed out in the appended claims.

It is to be understood that both the foregoing general description and the following detailed description are exemplary and explanatory only and are not restrictive of the invention, as claimed.

The accompanying drawings, which are incorporated in and constitute a part of this specification, illustrate embodiments of the invention and together with the description, serve to explain the principles of the invention.

### BRIEF DESCRIPTION OF THE DRAWINGS

FIGS. 1A-1D depict schematic illustration of an exemplary method for fabricating a semiconductor device according to various embodiments of the present invention.

FIG. 2 depict a schematic illustration of an exemplary semiconductor device in accordance with another embodiment of the present invention.

FIG. 3A shows a graph of an optical signal during etching of a deep ultra-violet (UV) resist versus time.

FIG. 3B shows a graph of an optical signal during etching of a deep ultra-violet (UV) resist over a bottom anti-reflective coating versus time.

### DESCRIPTION OF THE EMBODIMENTS

Reference will now be made in detail to the present embodiments, examples of which are illustrated in the accompanying drawings. Wherever possible, the same reference numbers will be used throughout the drawings to refer to the same or like parts.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5.

Although the exemplary methods and variations disclosed herein are described below as a series of acts, the present invention is not limited by the specific ordering of the acts. For example, some acts may occur in different orders and/or concurrently with other acts or events apart from those illustrated and/or described herein, in accordance with the invention. In addition, not all illustrated steps may be required to implement a methodology in accordance with the present invention.

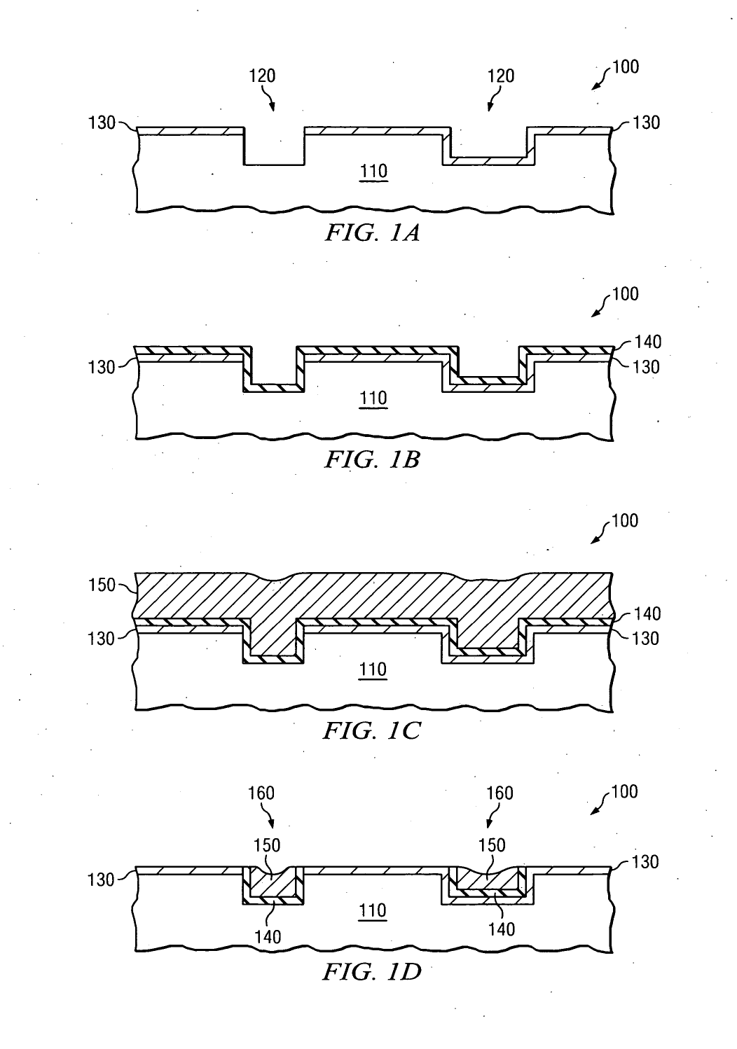

FIGS. 1A-1D illustrate a method of detecting planarization endpoint in accordance with the present teachings. As shown in FIG. 1A, the method can include forming a semiconductor structure 100 having at least one trench 120 in a first layer 110. As used herein, the term trench can also mean a hole, a via, a channel, or any depression in a layer. According to various embodiments, the first layer can be a resist layer, such as a deep ultra-violet (UV) or I-line photoresist. Yet in other embodiments, the first layer 110 can be any trenched Complementary Metal Oxide Semiconductor (CMOS) structure substrate layer, including those that are compatible with a bottom anti-reflection coating (BARC) spin on and thermal cure process. An exemplary BARC can be KRF-17B, manufactured by JSR Microelectronics and an exemplary deep UV planarization resist can be UV110, manufactured by Shipley or Rohm & Haas Electronic Materials (R&H). In certain embodiments, a metal layer 130 can be formed over the first layer 110, as is shown in FIG. 1A.

According to various embodiments, it may be desired to planarize the first layer 110 so as to remove trench 120. Exemplary trench depths can be from about 500 Å to about 3000 Å. The first layer 110 can also be planarized to provide a flat surface for depositing the next layer. In certain embodiment, the first layer can include a first layer of a microelectromechanical system (MEMS), such as a digital light processing device (DLP) or a digital micromirror device (DMD). The first MEMS layer can be planarized to provide a flat surface for depositing a second layer, such as a spacer layer. In some MEMS applications, the surface of the second layer can form a reflecting surface. Further, planarizing the first layer allows a more uniform thickness of the second layer. In cases where the surface of the second layer forms a reflecting surface, the thickness of the second layer can provide a “tilt angle” for the reflecting surface when the second layer is removed.

Turning to FIG. 1B, the method can also comprise forming a layer of optical enhancement medium 140 over the first layer 110 and the metal layer 130, when using metal layer 130. The optical enhancement medium 140 can be any material that is thin and that can enhance an optical amplitude emitted by a consuming plasma relative to a planarizing material, such as a sacrificial planarizing material 150 described below. The overall thickness of the optical enhancement medium can be from about 100 Å to about 1500 Å, and in some cases from about 600 Å to about 1200 Å and in other cases from about 300 Å to 600 Å. In certain embodiments of the invention, the layer of optical enhancement medium 140 can be an anti-reflective coating such as deep UV bottom anti-reflective coating (BARC). In various embodiments, the optical enhancement medium 140 can be a bottom anti-reflective coating KRF-17B, manufactured by JSR Microelectronics or the like. For example, a layer of KRF-17B can be formed over the metal layer 130 by spin coating to obtain a thickness of about 890 Å. However, according to various embodiments, the optical enhancement medium layer 140 can have a thickness from about 300 Å to about 1000 Å. Moreover, in some cases, the optical enhancement medium layer can have a thickness from about 800 Å to about 1400 Å in the corners of the trench 120. Still further, the optical enhancement medium layer 140 can have thickness from about 300 Å to about 1200 Å on the top of the planar surface. In general, it may be desired that the optical enhancement medium layer 140 be very thin.

As shown in FIG. 1C, a layer of sacrificial planarizing material 150 can be formed over the optical enhancement medium layer 140. According to various embodiments, the sacrificial planarizing material 150 can be a photoresist, such as an organic, an inorganic, or an organic/inorganic hybrid polymer, a chemical vapor deposited layer, or any other material capable of filling the trench and acting as a planarizing material. In certain embodiments, the sacrificial planarizing material 150 can be a deep UV photo-resist, such as UV 110 manufactured by Rohm & Haas Electronic Materials. For example, the photoresist UV 110 can be spin coated at high speed for better planarization to achieve a thickness of about 4000 Å. In some cases, the sacrificial planarizing material 150 can be exposed to UV light, such as when using a photoresist material, which can develop the photoresist material. Moreover, the sacrificial planarizing layer 150 can be formed by spin coating or chemical vapor deposition. According to various embodiments, the sacrificial planarizing layer 150 can have thickness from about 0.3 μm to about 3 μm. When using a deep UV photoresist, the sacrificial planarizing layer 150 can have a thickness of about 0.3 μm to about 2 μm.

Those skilled in the art will understand that the deposition of any layer of material may be accompanied by thermal or UV curing to dry the layer and remove solvents, or other small molecules.

After forming the sacrificial planarizing material 150, the sacrificial planarizing layer 150 and the anti-reflective layer 140 are etched. For example, they can be blanket etched. While etching, monitoring system, such as an optical system, can be used to monitor the removal of the sacrificial planarizing layer 150 and the optical enhancement medium layer 140. According to various embodiments, the optical system can include a monochromator to select a desired wavelength and a detector such as a high bandwidth photo cell. For example, a wavelength of 384 nm can be selected and the intensity is monitored in situ as the planarizing layer is being etched. The amplitude signal can be averaged over a 5 second time interval. One can choose the time interval for averaging depending on the etch rate of the planarizing material and the signal strength. After the removal of the planarizing material, the optical enhancement medium layer is etched and an increase in the optical amplitude at 384 nm can be observed. An etching endpoint can be defined accordingly anytime after the increase in signal is observed. For example, the endpoint can be defined when the signal reaches at least 105% of the averaged value previously found. The plasma can be allowed to etch for another time interval, such as about 5 more seconds to consume the remaining optical enhancement medium layer 140, such as that remaining over the metal upper surface. Therefore trenches and holes filled with planarizing material can be left with the completion of the planarization.

In various embodiments of the invention, a mixture of oxygen/helium can be used in the plasma etching. In other embodiments, other mixtures of gases such as, oxygen, chlorine, carbon tetrachloride, sulfur hexafluoride, silicon tetrachloride, other halocarbons can be used for etching to meet the rate, selectivity, and anisotropy requirement of the particular process, the planarizing material, and the optical enhancement medium layer to be etched.

According to yet another embodiment, etching can be carried out using a mixture of oxygen and helium in the plasma chamber. The vacuum level of the plasma chamber can be maintained at about 800 milli Torr, with the top electrode kept at about 40° C. and the bottom electrode at about 10° C. The oxygen flow rate can be about 20 sccm and the helium flow rate can be about 45 sccm.

FIG. 3A shows a graph of the intensity of an optical signal 370 obtained from the etching of a deep UV resist layer 110 as a function of time. For comparison, FIG. 3B shows a graph of the intensity of an optical signal 380 obtained from the etching of the deep UV photoresist 150 and the deep UV bottom anti-reflective (BARC) layer 140. The enhanced optical signal in FIG. 3B due to the etching of the deep UV bottom anti-reflective layer starting at 381 reaches a maxima at 382 before reaching the level 383 due to the etching of the deep UV resist layer. Complete removal of the deep UV bottom anti-reflective layer 140 from the metal layer 130 is depicted in FIG. 3B by the leveling of the optical signal 383.

The optical signals 370 and 380 in standard industry practice are the amplitude intensity of the optical emission in the UV-VIS from the plasma discharge. Chemical species in the plasma such as reactant species or etching by-products produce characteristic spectral lines. Tracking the emission intensity at one of the pre-selected wavelength constitutes the monitoring of the etching process optically. In FIGS. 3A and 3B, emission was monitored at 384.2 nm, although other wavelengths can also be monitored.

In FIG. 3B, the etching process can be stopped at a predetermined time after the first observation of the optical signal 381, corresponding to the removal of the sacrificial planarizing layer 150. One can determine the predetermined time based on the knowledge of the etching rate and the thickness of the optical enhancement medium layer 140. Thus, the etching can be stopped when the optical signal indicates that the sacrificial planarizing layer 150 has been removed. Because the etch rate of the optical enhancement medium layer 140 is known, this layer can be precisely removed to produce the intended planar geometry.

Turning back to FIG. 1D, the trenches 120 of the semiconductor structure 100 have been planarized, as shown by the filled trenches 160 using the optical enhancement medium layer as an optical end point detection signal medium. In various embodiments of the invention, using the deep UV BARC as the optical enhancement medium layer 140 and the deep UV photo-resist as the planarizing layer 150, surface planarity of about 1000 Å can be achieved. As such, a next layer of metal can have an “as manufactured” surface non-planarity of less than 150 Å.

In another embodiment, the etching process can be stopped before the complete removal of the optical enhancement medium layer 140. This left over optical enhancement medium layer 140 can be used as a bottom optical enhancement medium layer for the next photo-lithographic process in the manufacture of the semiconductor device.

In other embodiments, ashing can be used as an alternative to the plasma etching. According to this embodiment, ashing can be performed in a vacuum chamber heated to about 200° C. in a downstream flow of oxygen.

Moreover, in certain embodiments, the optical signals monitored for the end point detection can be the amplitude intensity of the optical emission from the plasma discharge at wavelengths in the range other than the spectral range of UV-VIS.

In various embodiments, the signal used to monitor the etching process can be a radio frequency power signal or an impedance change rather than an optical signal.

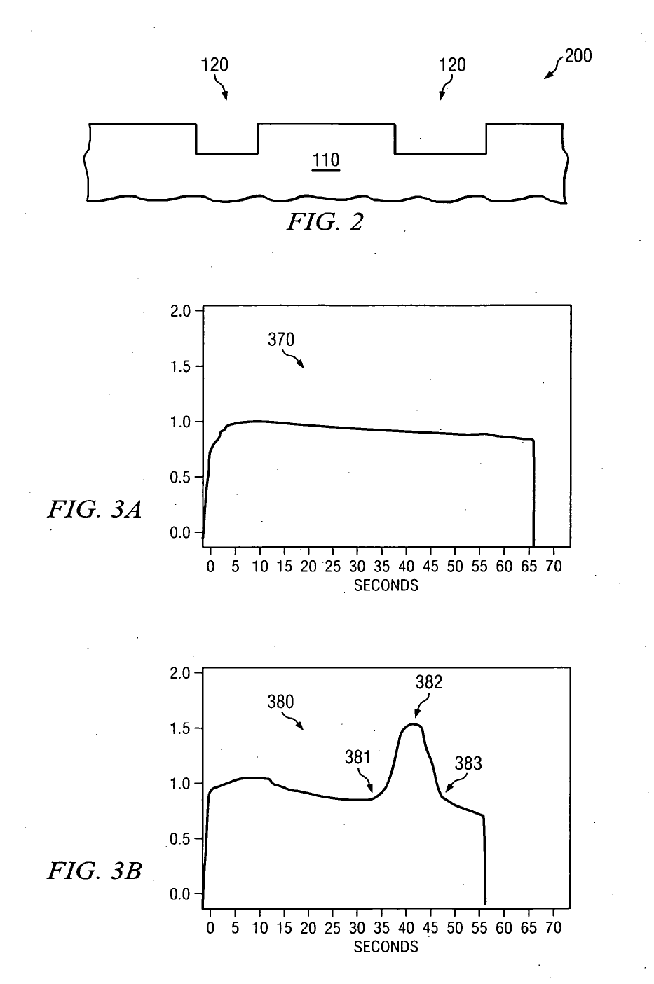

FIG. 2 provides a schematic illustration of yet another embodiment. In FIG. 2, a semiconductor device 200 can include a first layer 110 with one or more trenches 120. The first layer 110 can be a resist, a deep ultraviolet resist, a patterned substrate or any other layer to be planarized. However, in this embodiment a metal layer 130 need not be positioned over the first layer 110 and between first layer 110 and the optical enhancement medium layer 140. The process of planarization can continue in this embodiment in a similar manner to that described above in FIGS. 1B-1D.

Referring back to FIG. 1B, the optical enhancement medium layer 140 can include a bottom anti-reflective coating (BARC). BARC material can comprise organic, inorganic, or organic/inorganic hybrid polymers mixed with a dye. Exemplary BARC materials can include a dye mixed with a polymeric material comprising polyester, cellulose, heterocyclic, acrylate, organosiloxane. It is to be understood, however, that other BARC materials can also be used. Moreover the polymers can also be grafted with a dye with a functional group for use as a BARC material. Inorganic BARC materials such as Si_{X}O_{Y}N_{Z} can also be deposited by chemical vapor deposition. In general, organic BARC materials can have a thickness from about 600 Å to about 1200 Å, whereas inorganic BARC can have a thickness from about 300 Å to about 500 Å.

In an exemplary embodiment, a semiconductor device 100 is shown in FIG. 1C and FIG. D. The semiconductor device 100 can be fabricated to comprise a semiconductor substrate, a first layer 110 disposed over the semiconductor substrate, wherein the first layer comprises at least one trench 120, a metal layer 130 disposed over the first layer 110, an optical enhancement medium 140 disposed over at least one trench 120 and over the metal layer 130, and a layer of planarization material 150 disposed over the optical enhancement medium layer 140.

FIGS. 1A to 1D also illustrate a method of making a semiconductor device 100. The method can include forming a semiconductor substrate, forming a first layer 110 over the semiconductor substrate, wherein the first layer comprises at least one trench 120, and forming a metal layer 130 over the first layer 110 as is shown in FIG. 1A. The method can also include forming an optical enhancement medium layer 140 over at least one trench 120 and over the metal layer 130, as shown in FIG. 1B. The method can further include forming a layer of planarization material 150 over the optical enhancement medium layer 140, as shown in FIGS. 1C and 1D.

While the invention has been illustrated with respect to one or more implementations, alterations and/or modifications can be made to the illustrated examples without departing from the spirit and scope of the appended claims. In addition, while a particular feature of the invention may have been disclosed with respect to only one of several implementations, such feature may be combined with one or more other features of the other implementations as may be desired and advantageous for any given or particular function. Furthermore, to the extent that the terms “including”, “includes”, “having”, “has”, “with”, or variants thereof are used in either the detailed description and the claims, such terms are intended to be inclusive in a manner similar to the term “comprising.”

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A method of endpoint detection for an etching process comprising:
forming a semiconductor structure having at least one trench in a first layer;
forming a layer of anti-reflective coating over the trench and the first layer;
depositing a second layer over the layer of anti-reflective coating;
etching the second layer and the layer of anti-reflective;
monitoring the etching process; and
stopping the etching process at a predetermined time after observing a signal from the etching of the anti-reflective coating, whereby a etching endpoint is detected.

2. The method of claim 1, wherein the signal is one of an optical signal, a radio frequency power signal, or an impedance change.

3. The method of claim 1, wherein the first layer comprises a metal layer over a second layer.

4. The method of claim 1, wherein the first layer comprises a trenched complementary metal oxide semiconductor (CMOS) substrate layer.

5. The method of claim 1, wherein the anti-reflective coating comprises at least one of an organic bottom anti-reflective coating material (BARC) layer, an inorganic BARC layer, and a hybrid organic-inorganic BARC layer.

6. The method of claim 1, wherein the anti-reflective coating comprises a deep UV bottom anti-reflective coating material (deep UV BARC).

7. The method of claim 1, wherein the anti-reflective material comprises a material that provides an enhanced optical amplitude relative to the second layer material when etched in a plasma.

8. The method of claim 1, wherein the second layer comprises a resist.

9. The method of claim 1, wherein the second layer comprises a deep UV photo-resist.

10. The method of claim 1, wherein the signal is detected using an optical monitoring and detection system that utilizes optical emission spectroscopy.

11. A method of planarization comprising:
forming a layer of optical enhancement medium over a patterned surface comprising at least one trench;
depositing a planarizing-layer over the optical enhancement medium;
etching the planarizing layer and the optical enhancement medium layer;
optically monitoring the etching process; and
stopping the etching at a predetermined time after observing an optical signal from the optical enhancement medium.

12. The method of claim 11, wherein the anti-reflective coating comprises at least one of an organic bottom anti-reflective coating material (BARC) layer, an inorganic BARC layer, and a hybrid organic-inorganic BARC layer.

13. The method of claim 11, wherein the optical enhancement medium comprises a deep UV bottom anti-reflective coating material (deep UV BARC).

14. The method of claim 11, wherein the planarizing layer comprises a resist.

15. The method of claim 11, wherein the planarizing layer comprises a deep UV photo-resist.

16. A semiconductor device comprising:
a semiconductor substrate;
a first layer disposed over the semiconductor substrate, wherein the first layer comprises at least one trench;
a metal layer disposed over the first layer;
an optical enhancement medium layer disposed over the at least one trench and over the metal layer; and
a layer of planarization material disposed over the optical enhancement medium layer.

17. The semiconductor device of claim 16, wherein the optical enhancement medium comprises at least one of an organic bottom anti-reflective coating material (BARC) layer, an inorganic BARC layer, and a hybrid organic-inorganic BARC layer.

18. The semiconductor device of claim 16, wherein the optical enhancement medium comprises a deep UV bottom anti-reflective coating material (deep UV BARC).

19. The semiconductor device of claim 16, wherein the planarization material comprises a resist.

20. The semiconductor device of claim 16, wherein the planarization material comprises a deep UV photo-resist.

21. A method of making a semiconductor device, the method comprising:
forming a semiconductor substrate;
forming a first layer over the semiconductor substrate, wherein the first layer comprises at least one trench;
forming a metal layer over the first layer;
forming an optical enhancement medium layer over the at least one trench and over the metal layer; and
forming a layer of planarization material over the optical enhancement medium layer.

22. The method of making a semiconductor device according to claim 21, wherein the optical enhancement medium comprises at least one of an organic bottom anti-reflective coating material (BARC) layer, an inorganic BARC layer, and a hybrid organic-inorganic BARC layer.

23. The method of making a semiconductor device according to claim 21, wherein the optical enhancement medium comprises a deep UV bottom anti-reflective coating material (deep UV BARC).

24. The method of making a semiconductor device according to claim 21, wherein the planarization material comprises a resist.

25. The method of making a semiconductor device according to claim 21, wherein the planarization material comprises a deep UV photo-resist.
